(19) United States
(12) Patent Application Publication
(10) Pub. No.: US 2013/0168062 A1
(43) Pub. Date: Jul. 4, 2013

(54) WIND SHIELDING DEVICE AND HEAT DISSIPATION DEVICE USING THE SAME

(71) Applicant: YAO-TING CHANG, Tu-Cheng (TW)

(72) Inventor: YAO-TING CHANG, Tu-Cheng (TW)

(21) Appl. No.: 13/660,056

(22) Filed: Oct. 25, 2012

(30) Foreign Application Priority Data
Dec. 28, 2011 (TW) 100149166

(51) Int. Cl. H05K 7/20; F28F 13/12

(52) U.S. Cl. 165/104.34; 312/236

(57) ABSTRACT

A wind shielding device for a heat dissipating device of an electronic device includes a case defining an air outlet communicating with an exhaust hole of a blower, a plurality of blades rotatably received in the case, a retainer base fixed in the case, and a retainer element mounted on the retainer base. When wind blowing outwards from the exhaust hole spins the blades, the blades knock the retainer element out of the way, the retainer element is rotated and allows the blades to continuously rotate. When air from the outside attempts to enter the exhaust hole, the blades are spun to contact the other side of the retainer element, and the retainer element prevents further rotation in that direction.

### BACKGROUND

1. Technical Field

The present disclosure relates to heat dissipation devices for electronic devices, and particularly to a wind shielding device and a heat dissipation device using the same.

2. Description of Related Art

Many electronic devices, such as personal computers, have heat dissipation devices. A heat dissipation device of an electronic device may include a plurality of fans or blowers to generate air flows and dissipate heat generated in the electronic device quickly. However, in such a heat dissipation device, if one or more of the fans or blowers malfunctions, the air flows generated by the other fans or blowers may be forced in a wrong direction (i.e., backwards) and adversely affect heat dissipation of the electronic device.

For example, FIG. 4 shows a typical heat dissipation device 100 for an electronic device (not shown). The heat dissipation device 100 includes at least two blowers 10 and a housing 30. The two blowers 10 and electronic elements (not shown) of the electronic device, such as circuit boards, are all received in the housing 30. Each of the two blowers 10 defines an exhaust hole 11 opening outside the housing 30. When the heat dissipation device 100 is working normally, the two blowers 10 synchronously move air to dissipate heat generated by the electronic elements. However, if one blower 10 malfunctions and stops working while the other blower 10 still works normally, the heated air moved by the normally working blower 10 may flow back into the housing 30 via the exhaust hole 11 of the malfunctioning blower 10. Thus, the heat generated by the electronic elements is may be made to simply circulate within the inside of the electronic device.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figure.

FIG. 1 is a disassembled view of a heat dissipation device for an electronic device, according to an exemplary embodiment.

FIG. 2 is a schematic view of the heat dissipation device shown in FIG. 1 dissipating heat.

FIG. 3 is a schematic view of the heat dissipation device shown in FIG. 1 preventing heat reflux.

FIG. 4 is a heat dissipation device for an electronic device in related art.

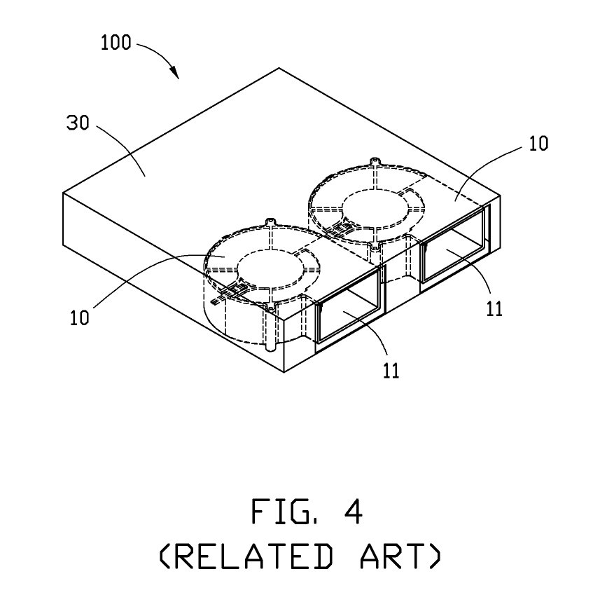

### DETAILED DESCRIPTION

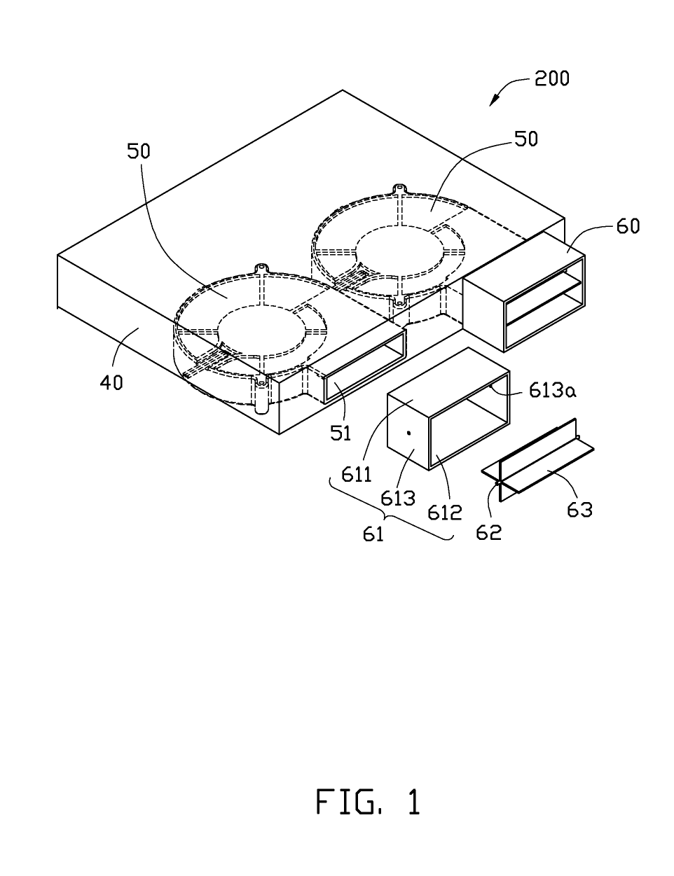

FIG. 1 shows a heat dissipation device 200, according to an exemplary embodiment. The heat dissipation device 200 can be utilized in an electronic device (not shown), such as a personal computer, to dissipate heat generated inside the electronic device.

The heat dissipation device 200 includes a housing 40, at least two blowers 50, and at least two wind shielding devices 60, each wind shielding device 60 corresponding to one of the blowers 50. The housing 40 can be a part of a typical housing of the electronic device. The two blowers 50 and commonly used electronic elements (not shown) of the electronic device, such as circuit boards, are all received in the housing 40. Each of the two blowers 50 defines an exhaust hole 51 opening out of the housing 40.

Each of the wind shielding device 60 includes a case 61, a shaft 62, a plurality of blades 63, a retainer base 65, and a retainer element 67. Each case 61 corresponds in size and shape to its respective exhaust holes 51. When, as shown in FIG. 1, the exhaust holes 51 are rectangular, the cases are rectangular and each include two side walls 611 and two end walls 613. The sidewalls 611 and the end walls 613 are all substantially planar sheets, and each of the two end walls 613 is perpendicularly connected between the two side walls 611 to form the case 61 and define a through air outlet 612. Each of the two end walls 613 defines a shaft hole 613a corresponding to the shaft 62. Two ends of the shaft 62 are rotatably received in the two shaft holes 613, respectively, so that the shaft 62 can rotate in the case 61. The blades 63 are all received in the air outlet 612, and radially and equidistantly fixed on the shaft 62. A width of each blade 63 substantially equals a width of each exhaust hole 51.

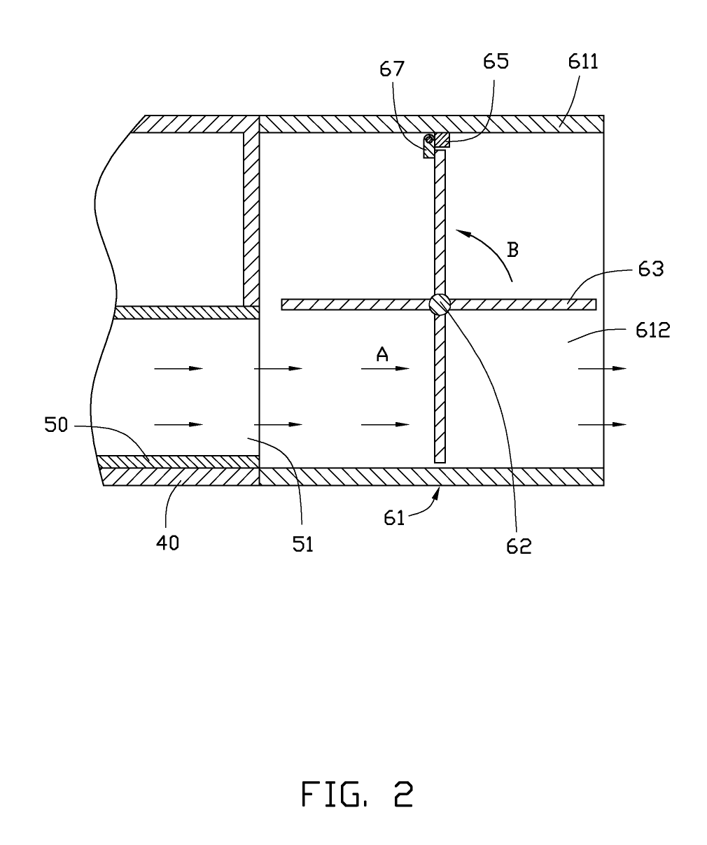

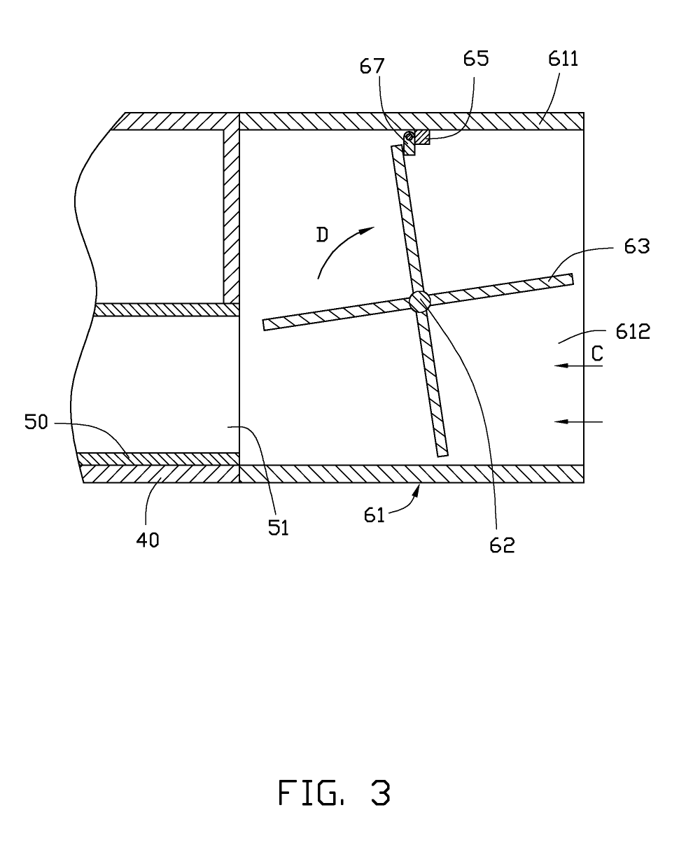

Also referring to FIG. 2 and FIG. 3, in each of the two wind shielding devices 60, the retainer base 65 is a protrusion formed on an inside surface of one of the two side walls 611. The retainer element 67 is a bar, and one end of the retainer element 67 is rotatably mounted (e.g., by a hinge) to a side of the retainer base 65 facing inwards (i.e., faces towards the housing 40 and the blowers 50). When a blade 63 rotates and contacts a side of the retainer element 67 facing downstream (e.g., as shown in FIG. 2, when the blades 63 rotate in the direction indicated by the arrow B and contact the retainer element 67), the retainer element 67 is driven to rotate back against the side wall 611 to which the retainer base 65 is fixed. Thus, the retainer element 67 does not stop or impede the rotation of the blade 63 in the direction of arrow B, and all blades 63 can continuously rotate. When a blade 63 rotates and contacts a side of the retainer element 67 upstream (that is, facing towards the blower 50, as shown in FIG. 3, when the blades 63 rotate in the direction of the arrow D and contact the retainer element 67), the retainer element 67 will not rotate because it is blocked by its point of attachment to the retainer base 65. Thus, the retainer element 67 stops the blade 63 from rotating further in the direction of arrow D, and all blades 63 remain in place.

In assembly, both the two cases 61 are fixed to the housing 40, and the air outlet 612 of each case 61 communicates with one exhaust hole 51. In particular, the exhaust hole 51 of each blower 50 is aligned with the portion of the air outlet 612 of the windshield device 60 which is on the side furthest from, and opposite to, the side to which the retainer base 65 and the retainer element 67 are attached.

In use, the two blowers 50 work together to generate an adequate air flow to dissipate heat generated in the electronic device quickly. As shown in FIG. 2, when both the two blowers 50 work normally, air flows outwards from the exhaust hole 51 of each blower 50 (i.e., in the direction of the arrow A). In each of the two wind shielding devices 60, the blades 63 are rotated in a direction as FIG. 2 is viewed. As detailed above, in this situation, the retainer element 67 permits the rotation of the blades 63, and all blades 63 can continuously rotate. Thus, the air flow generated by the two blowers 50 continuously moves outwards to dissipate heat.

As shown in FIG. 3, when one of the two blowers 50 malfunctions and stops working while the other blower 50 still works normally, the air flow generated by the normally working blower 50 may flow back into the case 61 of the wind shielding device 60 at a position corresponding to the malfunctioning blower 50 (i.e., along the arrow C, by locational accident and/or by a reduction of air pressure). In the wind shielding device 60 corresponding to the malfunctioning blower 50, the blades 63 in the portion of the air outlet 612 that does not receive the retainers 65 and the retainer elements 67 receive an inward pressure. However, the blades 63 in the other portion of the air outlet 612, diametrically opposite, are driven to rotate in the direction of the arrow D and contact the upstream side of the retainer element 67. As detailed above, in this situation, the retainer element 67 cannot rotate further, and therefore the blades 63 cannot rotate. Thus, the blades 63 are held in place, and provide a seal against outside air flowing into the case 61. In this way, heat reflux is prevented, and the heat dissipation device 100 can still dissipate heat by means of the still-functioning blower 50.

The heat dissipation device 100 can also include more than two blowers 50 and an equal number of wind shielding devices 60 corresponding to the blowers 50. Furthermore, the blowers 50 can also be replaced by fans.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A wind shielding device for a heat dissipation device of an electronic device, comprising:
a case defining an air outlet therein, the air outlet communicating with an exhaust hole of a blower of the heat dissipation device;
a plurality of blades rotatably received in the case;
a retainer base fixed in the case; and
a retainer element rotatably mounted on the retainer base;
wherein when wind blowing outwards from the exhaust hole contacts the blades, the blades contact a side of the retainer element, and the retainer element is rotated and allows the blades to continuously rotate; and when external wind blowing inwards through the air outlet contacts the blades, the blades contact an opposite side of the retainer element, and the retainer element is blocked by the retainer base and prevents the blades from rotating.

2. The wind shielding device of claim 1, further comprising a shaft rotatably received in the case, wherein the blades are fixed on the shaft.

3. The wind shielding device of claim 1, wherein the retainer base is a protrusion formed on an inner surface of the case, and the retainer element is a bar, and one end of the retainer element is rotatably mounted to a side of the retainer base facing to the blower.

4. The wind shielding device of claim 3, wherein when the blades rotate to contact a side of the retainer element facing against the blower, the retainer element is rotated and allows the blades to continuously rotate; and when the blades rotate to contact a side of the retainer element facing to the blower, the retainer element is blocked by the retainer base and stops the blades to rotate.

5. The wind shielding device of claim 1, wherein the exhaust hole is aligned with a portion of the air outlet that does not receive the retainer base and the retainer element therein.

6. The wind shielding device of claim 1, wherein a width of each of the blades substantially equals a width of the exhaust hole.

7. A heat dissipation device for an electronic device, comprising:
a housing;
at least two blowers received in the housing, each blower defining an exhaust hole opening out of the housing; and
at least two wind shielding devices, each wind shielding device corresponding to one of the blowers and including:
a case defining an air outlet therein, the air outlet communicating with the exhaust hole of the corresponding blower;
a plurality of blades rotatably received in the case;
a retainer base fixed in the case; and
a retainer element rotatably mounted on the retainer base;
wherein when wind blowing outwards from the exhaust hole of any blower blows the blades of the wind shielding device corresponding to the blower, the blades contact a side of the retainer element, and the retainer element is rotated and allows the blades to continuously rotate; and when external wind blowing inwards the air outlet of any wind shielding device and blows the blades, the blades contact another opposite side of the retainer element, and the retainer element is blocked by the retainer base and stops the blades to rotate.

8. The heat dissipation device of claim 7, wherein each wind shielding device further includes a shaft rotatably received in the case, and the blades are fixed on the shaft.

9. The heat dissipation device of claim 7, wherein the retainer base of each wind shielding device is a protrusion formed on an inner surface of the case, and the retainer element of the wind shielding device is a bar, and one end of the retainer element is rotatably mounted to a side of the retainer base facing to the blower corresponding to the wind shielding device.

10. The heat dissipation device of claim 9, wherein when the blades of any wind shielding device rotates to contact a side of the retainer element of the wind shielding device facing against the blower corresponding to the wind shielding device, the retainer element is rotated and allows the blades to continuously rotate; and when the blades rotates to contact a side of the retainer element facing to the blower, the retainer element is blocked by the retainer base and stops the blades to rotate.

11. The heat dissipation device of claim 7, wherein the exhaust hole of each blower is aligned with a portion of the air outlet of the wind shielding device corresponding to the blower that does not receive the retainer base and the retainer element of the wind shielding device therein.

12. The heat dissipation device of claim 7, wherein a width of each of the blades of any wind shielding device substantially equals a width of the exhaust hole of the blower corresponding to the wind shielding device.
